(19) United States
(12) Patent Application Publication
(10) Pub. No.: US 2014/0029228 A1
(43) Pub. Date: Jan. 30, 2014

(54) DISPLAY PANEL AND DISPLAY DEVICE

(71) Applicant: MITSUBISHI ELECTRIC CORPORATION, Tokyo (JP)

(72) Inventor: Takehisa YAMAGUCHI, Tokyo (JP)

(21) Appl. No.: 13/935,869

(22) Filed: Jul. 5, 2013

(30) Foreign Application Priority Data
Jul. 24, 2012 (JP) 2012-163408

(51) Int. Cl. H05K 7/02

(52) U.S. Cl. CPC H05K 7/02
USPC 361/784

(57) ABSTRACT

A substrate having a circuit component mounting area includes source wiring and a redundant pattern. A substrate is formed by cutting a part of a substrate disposed opposite to the substrate along a cutting line for exposing the circuit component mounting area. The source wiring is extended from an inner part of a display area to the circuit component mounting area. The redundant pattern is formed in a position corresponding to the cutting line and in the vicinity of the source wiring.

### BACKGROUND OF THE INVENTION

1. Field of the Invention

The present invention relates to a display panel and a display device which can deal with a failure such as disconnection.

2. Description of the Background Art

In every field, a display device spreads. For the display device, a liquid crystal display utilizing a liquid crystal occupies a mainstream. The liquid crystal display includes a TFT (Thin Film Transistor) array substrate, an opposed substrate which is disposed opposite to the TFT array substrate, and a liquid crystal layer.

The TFT array substrate has a display area for displaying a video and a circuit component mounting area formed around the display area. In the display area, a plurality of pieces of longitudinal wiring and a plurality of pieces of transverse wiring intersect with each other. A signal is transmitted from the wiring in an area provided around the display area to the pieces of wiring in the display area. An IC (Integrated Circuit) for outputting a signal, other circuit components and the like are mounted on the circuit component mounting area. The liquid crystal layer is provided between the TFT array substrate and the opposed substrate.

The circuit component mounting area of the liquid crystal display is exposed by superimposing the opposed substrate and the TFT array substrate and then cutting and removing a part of the opposed substrate which is opposed to the circuit component mounting area of the TFT array substrate.

After the circuit component mounting area is exposed, each piece of wiring of the display area, a driver IC for outputting a signal to an element, a power supply for driving the driver IC, an FPC to be connected to a circuit board for inputting a signal and the like are mounted on the circuit component mounting area.

A part of the opposed substrate is removed (the opposed substrate is cut) by attaching a cutting line (a scribe line) having a small depth onto an upper portion of the opposed substrate by means of a diamond cutter or the like and applying a load to the vicinity of the cutting line, for example.

According to the cutting method described above, a chip is generated in the step of cutting the opposed substrate and sticks to a surface of the TFT array substrate. Consequently, a protective film (an insulating film) of the TFT array substrate is damaged in some cases. Moreover, a discard end of the opposed substrate made in the cutting step comes in contact with the TFT array substrate so that the TFT array substrate is damaged in some cases. In these cases, there is a possibility that a failure, for example, peeling of a film of the TFT array substrate, a line defect such as disconnection, or the like might occur when an excessive load is applied to the TFT array substrate on which the chip is accumulated.

The line defect such as disconnection caused clearly in a manufacturing process is eliminated by drop-out (selection) through an inspection in the manufacturing process. For this reason, the line defect is one of factors of reduction in a yield of a product. Referring to a product having a flaw which does not cause the disconnection, moreover, there is also a possibility that the light defect might be caused in use at a market due to slip-out (omission) of the product in the inspection in the middle of the manufacturing process.

Japanese Patent Application Laid-Open No. 2003-222905 discloses the technique for restoring the disconnection of wiring in a display area (which will be hereinafter referred to as related art A). In the related art A, there is employed the redundant structure in which the conductive line is provided between the source wiring (line) and the gate wiring in a place other than the place in which the source wiring and the gate wiring cross each other (they are superimposed on each other). Referring to the related art A, in the case in which the disconnected part is confirmed, the wiring having the disconnected part is connected to the conductive line by the laser beam to restore the disconnected part.

More specifically, in the related art A, the structure for interposing the conductive line is employed between the gate wiring and the source wiring formed above the gate wiring in the display area. The conductive line is provided in parallel with each of the source wiring and the gate wiring. Furthermore, referring to the related art A, the conductive line which is parallel with the source wiring is not formed in the cross portion in which the source wiring and the gate wiring are superimposed on each other. In the case in which the disconnection occurs in the source wiring or the gate wiring, the vicinity of both ends of the disconnected portion is irradiated with a laser beam. Consequently, the wiring having the disconnected portion is connected to the conductive line through the wiring and the insulating film to restore the disconnected portion. In the related art A, all of the pieces of wiring in the display area are caused to have redundancy.

However, in the structure according to the related art A, a parasitic capacitance (capacity) is generated between the conductive line to be the redundant wiring and the source wiring or the gate wiring. Consequently, a high loaded condition is brought in order to electrically drive the structure according to the related art A so that distortion and delay of a signal are induced to cause deterioration in performance of a product.

Moreover, a place (space) for the redundant wiring is required for a plane layout in a pixel design. For this reason, an opening portion of a pixel is narrowed. Consequently, it is necessary to take a countermeasure such as a rise in a backlight luminance in order to obtain the same display luminance as that in the case in which the redundant wiring is not provided. For this reason, in the related art A, there is caused a factor for reducing the competitive ability of a product in the market, for example, increase in electric power consumption.

In the related art A, the factor is potentially possessed, and at the same time, a line defect (a failure) such as disconnection is caused more often when the wiring area (particularly, the circuit component mounting area) on an outside of the display area is exposed as compared with an inside of the display area. In other words, there is a high possibility that disconnection in the substrate having the circuit component mounting area might occur in the exposure of the circuit component mounting area. Accordingly, there is a high possibility that a failure such as disconnection of the wiring formed on the substrate having the circuit component mounting area might be caused in the vicinity of the circuit component mounting area.

The related art A does not specify a structure for restoring the failure such as the disconnection occurring in the vicinity of the circuit component mounting area in a structure using two substrates which are disposed opposite to each other. For this reason, the related art A has a problem in that the influence of the failure such as the disconnection occurring in the vicinity of the circuit component mounting area cannot be avoided.

### SUMMARY OF THE INVENTION

It is an object of the present invention to provide a display panel and the like which can avoid the influence of a failure occurring in the vicinity of a circuit component mounting area.

A display panel according to an aspect of the present invention includes a first substrate having a display area for displaying a video and a circuit component mounting area formed around the display area for mounting a circuit component thereon, and a second substrate disposed opposite to the first substrate, the second substrate is formed by cutting a part of a substrate disposed opposite to the first substrate along a cutting line for exposing the circuit component mounting area, and the first substrate includes first wiring extended from an inner part of the display area to the circuit component mounting area, and a redundant pattern formed in a position corresponding to the cutting line and in the vicinity of the first wiring.

According to the present invention, the first substrate having the circuit component mounting area includes the first wiring and the redundant pattern. The second substrate is formed by cutting a part of the substrate disposed opposite to the first substrate along the cutting line for exposing the circuit component mounting area. The first wiring is extended from the inner part of the display area to the circuit component mounting area. The redundant pattern is formed in the position corresponding to the cutting line and in the vicinity of the first wiring.

Consequently, it is possible to avoid the influence of a failure such as the disconnection of the first wiring included in the first substrate having the circuit component mounting area which is likely to occur in the vicinity of the circuit component mounting area. In other words, it is possible to avoid the influence of the failure occurring in the vicinity of the circuit component mounting area.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing a structure of a display device according to a first preferred embodiment of the present invention;

FIG. 2 is a sectional view showing a display panel according to the first preferred embodiment of the present invention;

FIG. 3 is a plan view showing a part of the display panel according to the first preferred embodiment of the present invention;

FIG. 4 is a sectional view showing the display panel according to the first preferred embodiment of the present invention;

FIG. 5 is a plan view showing a whole substrate;

FIG. 6 is a sectional view showing a process for manufacturing the substrate;

FIG. 7 is a plan view showing a substrate acting as an opposed substrate;

FIG. 8 is a view for explaining a step to be executed until a circuit component mounting area is exposed;

FIG. 9 is a view for explaining a repair process;

FIG. 10 is a view showing a redundant pattern which specifies an identification mark;

FIG. 11 is a plan view showing a part of a display panel according to a second preferred embodiment of the present invention;

FIG. 12 is a sectional view showing the display panel according to the second preferred embodiment of the present invention;

FIG. 13 is a view for explaining a repair process;

FIG. 14 is a plan view showing a part of a display panel according to a third preferred embodiment of the present invention;

FIG. 15 is a sectional view showing the display panel according to the third preferred embodiment of the present invention;

FIG. 16 is a plan view showing a part of a display panel according to a fourth preferred embodiment of the present invention; and

FIG. 17 is a sectional view showing the display panel according to the fourth preferred embodiment of the present invention.

### DESCRIPTION OF THE PREFERRED EMBODIMENTS

Preferred embodiments according to the present invention will be described below with reference to the drawings. In the following description, the same components have the same reference numerals. Their names and functions are also the same. Accordingly, repetitive description will be appropriately omitted in some cases.

Dimensions, materials, shapes, their relative arrangements of respective components shown in the preferred embodiments and the like are properly changed depending on a structure of a device to which the present invention is applied or various conditions, and the present invention is not restricted to their exemplification. Moreover, the dimension of each component in each drawing is different from an actual dimension in some cases.

### First Preferred Embodiment

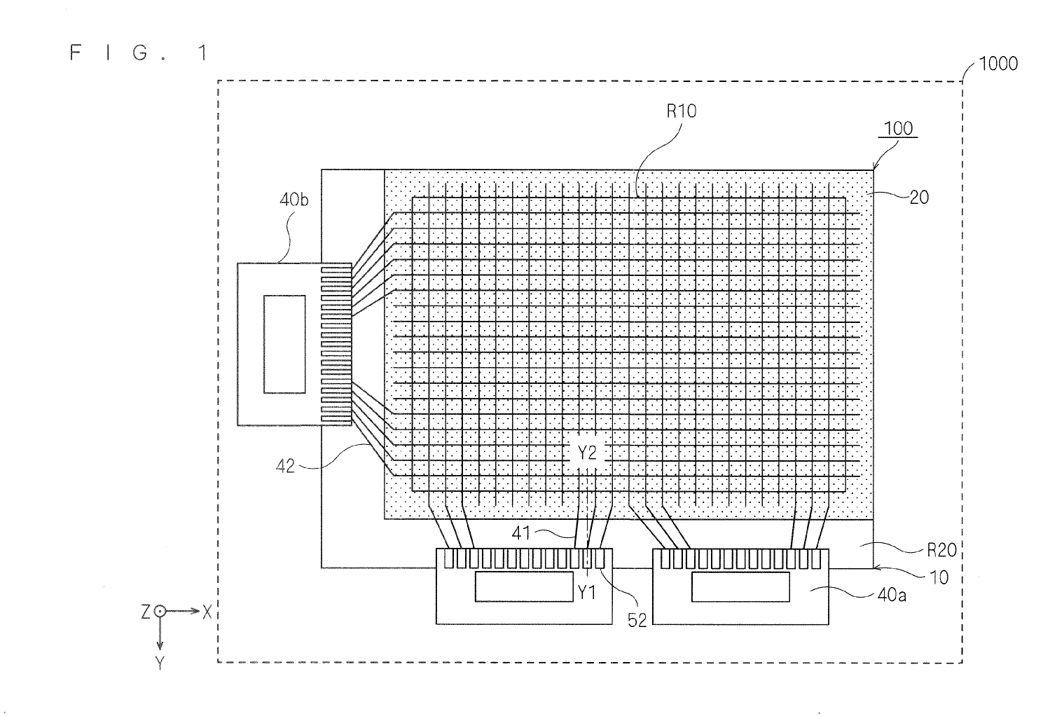

FIG. 1 is a plan view showing a structure of a display device 1000 according to a first preferred embodiment of the present invention. The display device 1000 is a liquid crystal display as an example. The display device 1000 is not restricted to the liquid crystal display but may be a display device of another type which has a structure using two substrates disposed opposite to each other.

In FIG. 1, X, Y and Z directions are orthogonal to each other. X, Y and Z directions shown in the following drawings are also orthogonal to each other. In the following, a direction including the X direction and an opposite direction to the X direction (a −X direction) will also be referred to as an X-axis direction. Moreover, in the following, a direction including the Y direction and an opposite direction to the Y direction (a −Y direction) will also be referred to as a Y-axis direction. Furthermore, in the following, a direction including the Z direction and an opposite direction to the Z direction (a −Z direction) will also be referred to as a Z-axis direction.

The display device 1000 includes a display panel 100. The display panel 100 is a liquid crystal display panel as an example. The display panel 100 is not restricted to the liquid crystal display panel but may be a display panel of another type which has a structure using two substrates disposed opposite to each other. The display device 1000 also includes a circuit or the like (not shown) which serves to control the display panel 100.

The display panel 100 includes substrates 10 and 20. The substrates 10 and 20 will be described below in detail. In FIG. 1, for easy understanding of a structure, the substrate 20 is perspectively shown. Moreover, the display panel 100 has a display area R10 and a circuit component mounting area R20. The display area R10 serves to display a video (an image). The display area R10 is constituted by a plurality of pixel portions (pixels) (not shown) which is arranged in a matrix.

The circuit component mounting area R20 serves to mount a circuit component thereon. As shown in FIG. 1, the circuit component mounting area R20 has no substrate 20 in the substrate 10. In FIG. 1, the circuit component mounting area R20 takes an L shape as an example. The circuit component mounting area R20 is included in an area provided around the display area R10. In other words, the circuit component mounting area R20 is formed around the display area R10.

The display panel 100 further includes a plurality of pieces of source wiring 41, a plurality of pieces of gate wiring 42, and FPCs (Flexible Printed Circuits) 40a and 40b.

The pieces of source wiring 41 are extended in a vertical direction (the Y-axis direction) in the display area R10. Each of the pieces of the source wiring 41 transmits a data signal to a corresponding one of the pixel portions.

The pieces of gate wiring 42 are extended in a horizontal direction (the X-axis direction) in the display area R10. Each of the pieces of the gate wiring 42 is utilized for selecting a pixel portion (a pixel) storing data. The gate wiring 42 is extended from an inner part of the display area R10 to the circuit component mounting area R20.

In FIG. 1, for simplification of the drawing, a part of the pieces of the gate wiring 42 and a part of the pieces of the source wiring 41 are shown so as not to be extended to the circuit component mounting area R20. Actually, the pieces of gate wiring 42 and the pieces of source wiring 41 which are included in the display panel 100 are extended to the circuit component mounting area R20.

A contact area is formed in the circuit component mounting area R20. The FPCs 40a and 40b are connected to the contact area.

A driver IC is mounted on each of the FPCs 40a and 40b. Moreover, a transparent electrode 52 which will be described below is formed in each of the FPCs 40a and 40b.

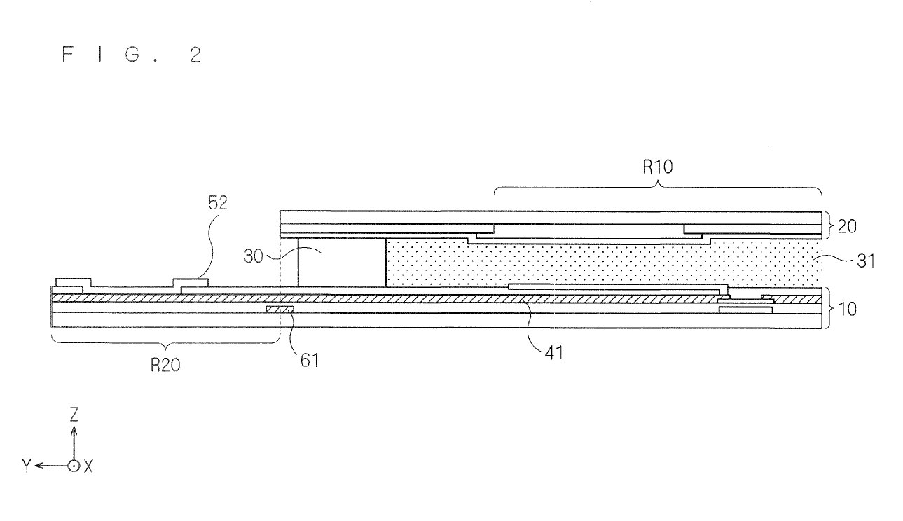

FIG. 2 is a sectional view showing the display panel 100 according to the first preferred embodiment of the present invention. More specifically, FIG. 2 is a sectional view showing the display panel 100 taken along a Y1-Y2 line in FIG. 1.

With reference to FIGS. 1 and 2, the display panel 100 further includes a liquid crystal layer 31 and a sealing material 30.

The substrate 10 is a TFT array substrate having a plurality of TFTs formed in an array. The substrate 10 has the display area R10 and the circuit component mounting area R20. Moreover, the substrate 10 includes the source wiring 41 extended from the inner part of the display area R10 to that of the circuit component mounting area R20. In other words, the source wiring 41 is extended from the inner part of the display area R10 to the circuit component mounting area R20.

The substrate 20 is an opposed substrate (a color filter substrate) which is disposed opposite to the substrate 10.

The substrates 10 and 20 are connected to each other through the sealing material 30 under a black matrix area (a BM area) on an outermost periphery of the display area R10. In other words, the sealing material 30 connects the substrates 10 and 20 to each other. The sealing material 30 is formed between the display area R10 and the circuit component mounting area R20 in the Y-axis direction. The Y-axis direction is a direction along a main surface of the substrate 10. The main surface of the substrate 10 is a surface of the substrate 10 which is opposed to the substrate 20.

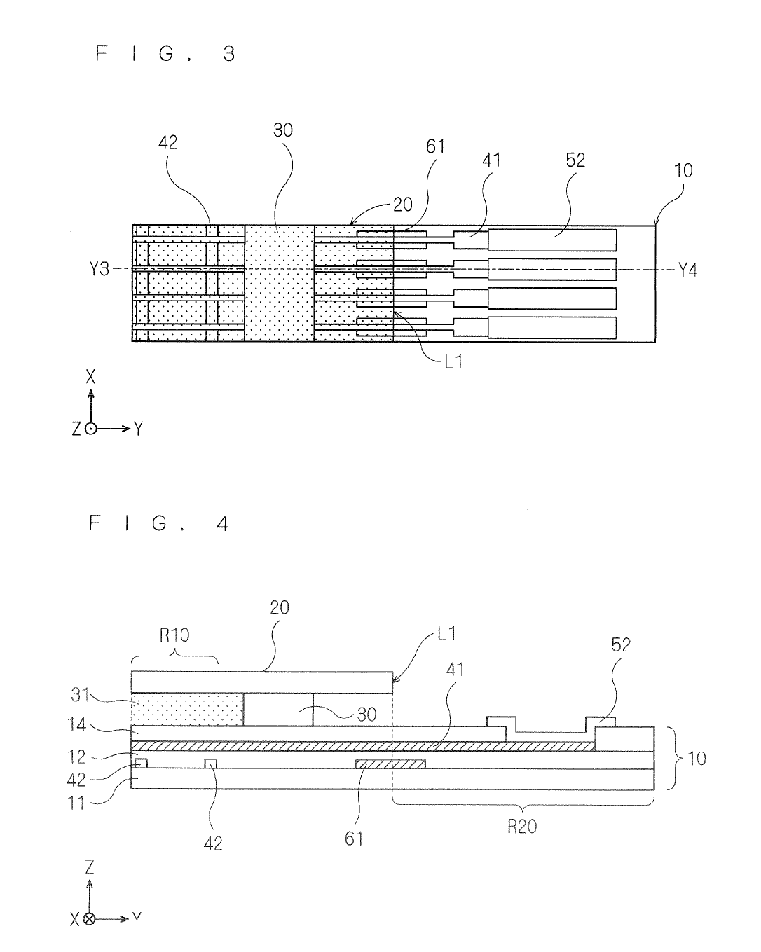

FIG. 3 is a plan view showing a part of the display panel 100 according to the first preferred embodiment of the present invention. More specifically, FIG. 3 is an enlarged view showing the vicinity of the Y1-Y2 line in FIG. 1. FIG. 4 is a sectional view showing the display panel 100 taken along a Y3-Y4 line in FIG. 3.

With reference to FIGS. 3 and 4, the substrate 10 includes a glass substrate 11, an interlayer insulating film 12, a passivation film 14, the source wiring 41, the gate wiring 42 and a redundant pattern 61 which will be described below.

The gate wiring 42 (the gate wiring film) is laminated on the glass substrate 11. Moreover, the interlayer insulating film 12 is laminated on the glass substrate 11 in order to cover the gate wiring 42 and the redundant pattern 61 which will be described below. The interlayer insulating film 12 is a silicon nitride film, for example.

An amorphous silicon film (not shown) for forming a TFT to be a switching element is subjected to patterning over the interlayer insulating film 12 and the source wiring 41 (the source wiring film) is then formed.

Each of the redundant pattern 61 which will be described below and the source wiring 41 is extended in a predetermined direction (the Y-axis direction). Moreover, the redundant pattern 61 and the source wiring 41 are provided close to each other. The passivation film 14 and the transparent electrode 52 are formed on the source wiring 41.

The substrate 20 acting as the opposed substrate will be described below in detail, and includes a black matrix layer, a coloring material layer, a transparent electrode and the like which are not shown.

An alignment film (not shown) is applied to a surface of the substrate 10 and a surface of the substrate 20 which is opposed to the surface of the substrate 10. The liquid crystal layer 31 is provided between the substrates 10 and 20. More specifically, the liquid crystal layer 31 is provided in a space constituted by the substrate 10, the substrate 20 and the sealing material 30. For easy understanding of the presence of the liquid crystal layer 31, a thickness of the liquid crystal layer 31 is exaggeratedly shown in FIG. 4. Actually, the thickness of the liquid crystal layer 31 is considerably smaller as compared with the thicknesses of the substrates 10 and 20 and the like. For this reason, the substrate 10 is provided in the vicinity of the substrate 20.

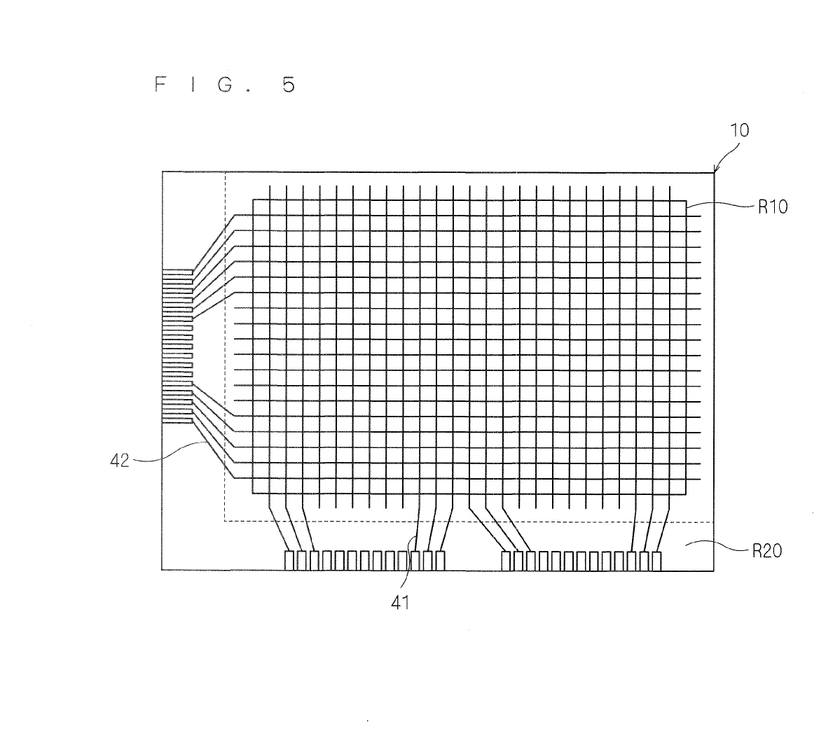

Next, a process for manufacturing the substrate 10 acting as the TFT array substrate will be described with reference to FIGS. 5 and 6. FIG. 5 is a plan view showing the whole substrate 10. In FIG. 5, the substrate 10 has the display area R10 and the circuit component mounting area R20 as described above. FIG. 6 is a sectional view showing the process for manufacturing the substrate 10. A peripheral area including the circuit component mounting area R20 is provided around the display area R10.

In a gate wiring forming step, first of all, a metal film is formed on the glass substrate 11 by means of a sputtering device in order to form the gate wiring 42 on the glass substrate 11 as shown in part (a) in FIG. 6. Then, resist coating, pattern exposure and development are carried out by a photoengraving device to process the metal film through etching. Consequently, the gate wiring 42 is formed in the display area R10.

In the gate wiring forming step, the redundant pattern 61 is formed in an opposed position to a cutting line L1 of the substrate 20 in the glass substrate 11 which will be described below. The redundant pattern 61 is extended in a direction in which the source wiring 41 is extended (the Y-axis direction). The redundant pattern 61 is constituted by a conductor (for example, a metal).

Thereafter, as shown in part (b) in FIG. 6, the interlayer insulating film 12 (the silicon nitride film) is formed by means of a CVD device. As shown in part (c) in FIG. 6, next, the amorphous silicon layer is formed. The amorphous silicon layer serves to form the TFT in the pixel of the display area. Then, an amorphous silicon film 13 is formed by photoengraving (resist coating, pattern exposure, development and resist removal) and etching.

Subsequently, as shown in part (d) in FIG. 6, a metal film is formed by means of the sputtering device in order to form the source wiring 41. Thereafter, the photoengraving (the resist coating, the pattern exposure, the development and the resist removal) and the etching are carried out. Consequently, the source wiring 41 (the source wiring film) is formed. Thus, there is obtained a structure in which a part of the interlayer insulating film 12 is interposed between the redundant pattern 61 formed in the gate wiring forming step and the source wiring 41 in a place which is opposed (corresponds) to the cutting line L1 of the substrate 20.

As shown in part (e) in FIG. 6, furthermore, the passivation film 14 acting as a protective film (an insulating film) is formed by means of the CVD device. The passivation film 14 is a silicon nitride film, for example. Then, a contact hole is formed on the gate wiring metal film and the source wiring 41 by the photoengraving (the resist coating, the pattern exposure, the development and the resist removal).

Finally, as shown in part (f) in FIG. 6, a transparent electrode film is formed by means of the sputtering device so that the transparent electrode 52 is formed on the transparent electrode in the pixel of the display area and the contact hole of the circuit component mounting area R20. From the foregoing, the substrate 10 including the redundant pattern 61 is formed as shown in FIG. 2 and the part (f) in FIG. 6.

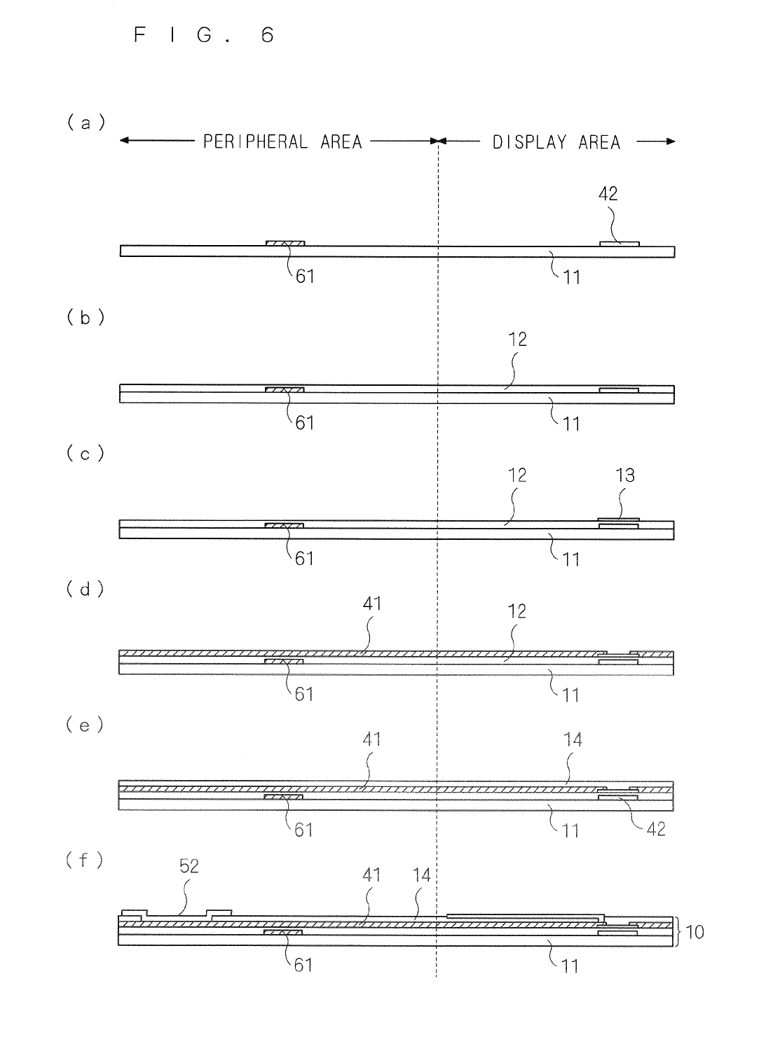

Thereafter, a substrate 20n (an opposed substrate) in FIG. 7 is provided opposite to the substrate 10. In other words, the substrate 20n (the opposed substrate) is provided to be superimposed on the substrate (the TFT array substrate) 10. In the substrate 20n, a part (an area R21) of the substrate 20n for exposing the circuit component mounting area R20 has not been cut. The substrate 20n has an equal size to that of the substrate 10. The substrate 20n has the area R21 which is opposed to the circuit component mounting area R20 of the substrate 10. The area R21 portion is not required for the substrate 20n. The area R21 of the substrate 20n is constituted by a material containing glass.

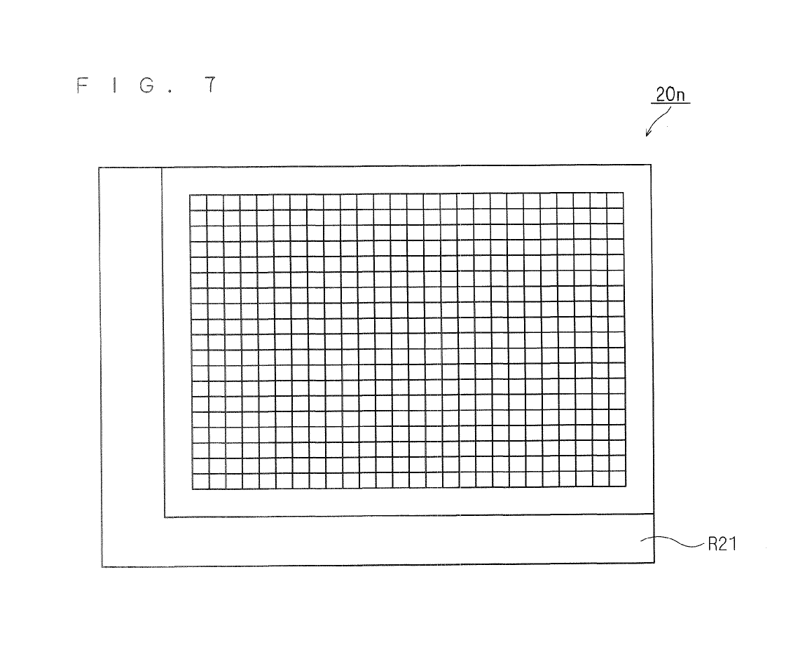

With reference to FIG. 8, next, description will be given to a process to be executed until the circuit component mounting area R20 is exposed. FIG. 8 is a view for explaining the process to be executed until the circuit component mounting area R20 is exposed.

As shown in part (a) in FIG. 8, the substrate 20n (the opposed substrate) is constituted by a glass substrate 21, a black matrix area 22, a coloring material layer 23 and a transparent electrode 24.

The black matrix area 22 is provided around the display area R10. In other words, the black matrix area 22 is provided on the outside of the display area R10.

The alignment film (not shown) is applied to the surface of the substrate 10 and the surface of the substrate 20n which is opposed to the surface of the substrate 10. The alignment film serves to determine an orientation of a liquid crystal of the liquid crystal layer 31 in the display area R10. The surfaces of the substrates 10 and 20n coated with the alignment film are treated with a rubbing cloth. In the part (a) in FIG. 8, neither alignment film coating nor rubbing is shown.

Next, the black matrix area 22 of the substrate 20n is coated with the sealing material 30. The substrate 20n coated with the sealing material 30 is disposed to be superimposed on the substrate (TFT array substrate) 10. Consequently, the structure in the (a) in FIG. 8 is obtained.

Subsequently, a cutting step is executed. In the cutting step, the cutting line L1 in a vertical direction is formed in a part of the substrate 20n in order to expose the circuit component mounting area R20 of the substrate 10 as shown in part (b) in FIG. 8. The cutting line L1 serves to cut the area R21 portion in FIG. 7. In other words, the cutting line L1 serves to expose the circuit component mounting area R20. More specifically, a position in the Y-axis direction of the cutting line L1 corresponds to a position of one of ends of the circuit component mounting area R20. As described above, the Y-axis direction corresponds to a direction along the main surface of the substrate 10.

For this reason, the cutting line L1 is disposed in the vicinity of the end of the circuit component mounting area R20 in the direction (the Y-axis direction) along the main surface of the substrate 20n (the substrate 10). In other words, the cutting line L1 is disposed on an outside of the position of the sealing material 30 in the direction (the Y-axis direction) along the main surface of the substrate 20n (the substrate 10). The cutting line L1 is formed by means of a diamond cutter, a wheel device or the like.

After the cutting line L1 is formed, the cutting line L1 is pressurized so that the area R21 portion (an unnecessary part of the substrate 20n) is cut as shown in part (c) in FIG. 8. In the following, the area R21 portion will also be referred to as a discard end 21n. The area R21 portion (the discard end 21n) in the substrate 20n is cut so that the substrate 20 is formed. In other words, the substrate 20 is formed by cutting a part of the substrate 20n (the discard end 21n) disposed opposite to the substrate 10 along the cutting line L1. Accordingly, the cutting line L1 corresponds to a position of an end face of the substrate 20 in the Y-axis direction.

From the foregoing, the redundant pattern 61 is formed in an opposed position to the cutting line L1 of the substrate 20n in the substrate 10 as shown in the part (c) in FIG. 8 and FIGS. 3 and 4. More specifically, the redundant pattern 61 is formed in a position which overlaps with a part of the source wiring 41 in the direction along the main surface of the substrate 10 and is different from the source wiring 41 in a vertical direction of the substrate 10. In other words, the redundant pattern 61 is formed in the position corresponding (opposed) to the cutting line L1 and in the vicinity of the source wiring 41.

As shown in FIG. 4 and the part (c) in FIG. 8, the redundant pattern 61 is provided in such a manner that a position of a central part in the Y-axis direction of the redundant pattern 61 is opposed to the cutting line L1. The Y-axis direction corresponds to a direction along the main surface of the substrate 10.

The redundant pattern 61 may be provided in such a manner that the position of the central part in the Y-axis direction of the redundant pattern 61 is set to be a position in the vicinity of the opposed position to the cutting line L1.

Then, a liquid crystal is injected into the space formed by the substrate 10, the substrate 20 and the sealing material 30 so that the liquid crystal layer 31 is formed. Consequently, the display panel 100 is fabricated.

As shown in part (d) in FIG. 8, in some cases in which the discard end 21n is cut, the discard end 21n comes in contact with the substrate 10. In these cases, a flaw 71 is given to a surface part (the passivation film 14) of the substrate 10 in which a chip generated in the cutting step is accumulated and the source wiring 41 provided under the passivation film 14 so that the source wiring 41 is disconnected. In other words, there is a high possibility that a failure such as disconnection might occur in the circuit component mounting area R20 and the vicinity of the circuit component mounting area R20.

Therefore, the display panel 100 thus fabricated is subjected to a display inspection before a circuit component is mounted on the circuit component mounting area R20. In the display inspection, there is executed an inspection for finding a failure, for example, the disconnection of wiring such as the source wiring 41.

In the present preferred embodiment, in the case in which a disconnected wiring, wiring which might be disconnected or the like is detected by the inspection, a repair process is carried out.

Next, description will be given to the repair process to be carried out when the failure such as the disconnection is detected in the present preferred embodiment.

It is assumed that the flaw 71 causing the disconnection of the source wiring 41 is made in the cutting step as shown in FIG. 9. In this case, a laser repairing device or the like irradiates two places of the redundant pattern 61 with a laser beam, the two places of the redundant pattern 61 being respectively close to two places of the source wiring 41 interposing the flaw 71 (a disconnected portion) from the back face of the substrate 10 in the repair process. Consequently, a part of the redundant pattern 61 is molten so that a molten portion 61m is generated. The two places of the source wiring 41 interposing the flaw 71 therebetween are electrically connected through the redundant pattern 61 by the molten portion 61m. In other words, the redundant pattern 61 electrically connects the two places of the source wiring 41 through irradiation of the laser beam on two places of the redundant pattern 61 which are respectively close to the two places of the source wiring 41 interposing the disconnected portion (the flaw 71) therebetween. More specifically, the redundant pattern 61 is a pattern for connecting the disconnected portions.

From the foregoing, the redundant pattern 61 is used for electrically connecting the two places of the source wiring 41 which interpose the disconnected portion (the flaw 71) therebetween when the disconnected portion (the flaw 71) is present in the source wiring 41 in the vicinity of the redundant pattern 61. In other words, the redundant pattern 61 serves to avoid the influence of the failure such as the disconnection of the source wiring 41.

Consequently, a place in which the flaw 71 causing the disconnection of the source wiring 41 is made is avoided so that the disconnection of the source wiring 41 is restored. Therefore, it is possible to suppress deterioration in a manufacturing yield.

As described above, according to the present preferred embodiment, the substrate 10 having the circuit component mounting area R20 includes the source wiring 41 and the redundant pattern 61. The substrate 20 is formed by cutting a part of the substrate 20n disposed opposite to the substrate 10 along the cutting line L1 for exposing the circuit component mounting area R20. The source wiring 41 is extended from the inner part of the display area R10 to the circuit component mounting area R20. The redundant pattern 61 is formed in the position corresponding (opposed) to the cutting line L1 in the substrate 10 and in the vicinity of the source wiring 41.

Consequently, it is possible to avoid the influence of the failure such as the disconnection of the wiring (for example, the source wiring 41) included in the substrate 10 which is likely to be caused in the vicinity of the circuit component mounting area R20. More specifically, it is possible to avoid the influence of the failure caused in the vicinity of the circuit component mounting area R20.

In other words, according to the structure in accordance with the present preferred embodiment, the redundant pattern 61 is provided on the substrate 10 which is opposed to the cutting line L1 for exposing the circuit component mounting area R20 of the substrate 10. The redundant pattern 61 is formed in the position opposed to the cutting line L1 and in the vicinity of the source wiring 41. Moreover, the redundant pattern 61 is provided to interpose the interlayer insulating film 12 between the source wiring 41 and the redundant pattern 61.

By the structure, also in the case in which the flaw causing the disconnection of the source wiring 41 is made by the cut discard end or the like in the step of cutting the opposed substrate (the substrate 20n), it is possible to restore the disconnection of the source wiring 41 including the place having the flaw by means of the laser repair or the like. Consequently, it is possible to prevent the manufacturing yield from being decreased due to the disconnection or the like without deteriorating the characteristic of the display panel or reducing a degree of design freedom in the display panel. Therefore, according to the present preferred embodiment, it is possible to provide a display panel having high reliability and a display device including the display panel.

Moreover, in the description, the redundant pattern 61 is formed in order to avoid the influence of the failure such as the disconnection from the source wiring 41. In other words, although the redundant pattern 61 is formed corresponding to the source wiring 41, the present invention is not restricted thereto. The redundant pattern 61 may be formed corresponding to the gate wiring 42.

More specifically, although it is assumed that the redundant pattern 61 is extended in the direction (the Y-axis direction) in which the source wiring 41 is extended, the present invention is not restricted thereto. The redundant pattern 61 may be provided to be extended in a direction (the X-axis direction) in which the gate wiring 42 is extended. In this case, the redundant pattern 61 is provided with a structure in which the source wiring 41 and the gate wiring 42 are replaced with the gate wiring 42 and the source wiring 41 respectively in FIG. 3. With the structure, similarly, it is possible to obtain the same effects as those described above. In other words, also in the case in which the flaw causing the disconnection of the gate wiring 42 is made in the gate wiring 42, it is possible to restore the disconnection of the gate wiring 42 by the same process as the repair process described with reference to FIG. 9.

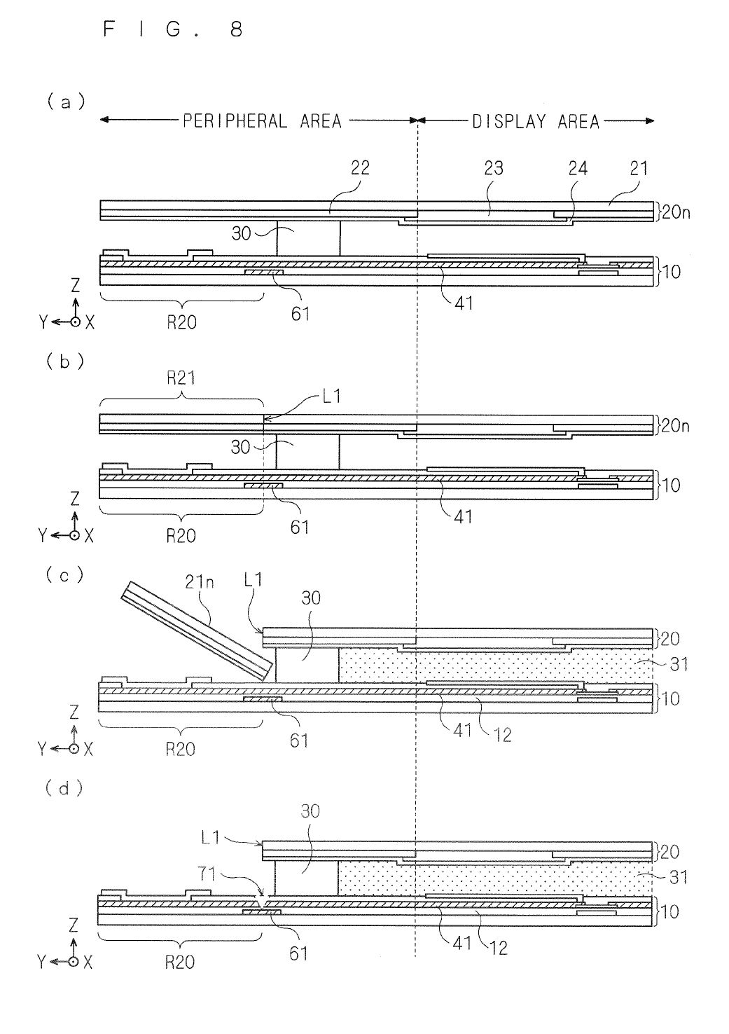

An identification mark may be specified on the surface of the redundant pattern 61. FIG. 10 is a view showing the redundant pattern 61 having the identification mark specified thereon. Part (a) in FIG. 10 is a view shown with simplification of FIG. 3. Part (b) in FIG. 10 is a view showing a state in which an identification mark 62 is specified on the surface of the redundant pattern 61. The identification mark 62 is a wiring address, for example.

By specifying the identification mark on the surface of the redundant pattern 61, thus, it is also possible to restore the wiring in the disconnection of the wiring and to utilize the identification mark as the wiring address.

### Second Preferred Embodiment

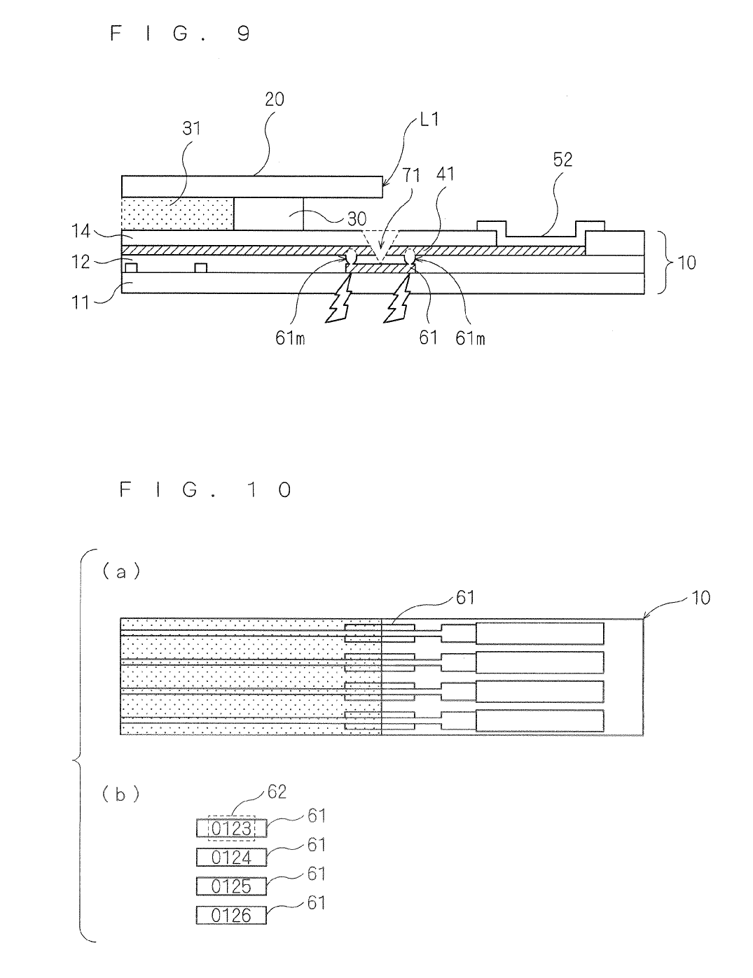

FIG. 11 is a plan view showing a part of a display panel 100A according to a second preferred embodiment of the present invention. FIG. 11 is an enlarged view showing a part of the display panel 100A in the same manner as FIG. 3. FIG. 12 is a sectional view showing the display panel 100A taken along a Y5-Y6 line in FIG. 11. A display device according to the present preferred embodiment includes the display panel 100A.

With reference to FIGS. 11 and 12, the display panel 100A is different from the display panel 100 according to the first preferred embodiment in that the display panel 100A includes a redundant pattern 61a in place of the redundant pattern 61. Since the other structures of the display panel 100A are the same as those of the display panel 100, detailed description will not be repeated.

The redundant pattern 61a has a different length as compared with the redundant pattern 61 in FIG. 4. Since the other structures of the redundant pattern 61a are the same as those of the redundant pattern 61, detailed description will not be repeated.

In the same manner as the redundant pattern 61, the redundant pattern 61a is formed in the gate wiring forming step. Each of the redundant pattern 61a and source wiring 41 is extended in a predetermined direction (a Y-axis direction). Moreover, the redundant pattern 61a and the source wiring 41 are provided close to each other.

Furthermore, the redundant pattern 61a is extended across a position of a sealing material 30. In other words, the redundant pattern 61a is extended from an inner part of a circuit component mounting area R20 to that of a display area R10. More specifically, one of ends of the redundant pattern 61a is disposed on an inside of the position of the sealing material 30 in the display panel 100A. Accordingly, it is possible to reduce a possibility that a damage caused by a laser beam to the redundant pattern 61a might be exposed into the air, resulting in occurrence of a failure such as corrosion.

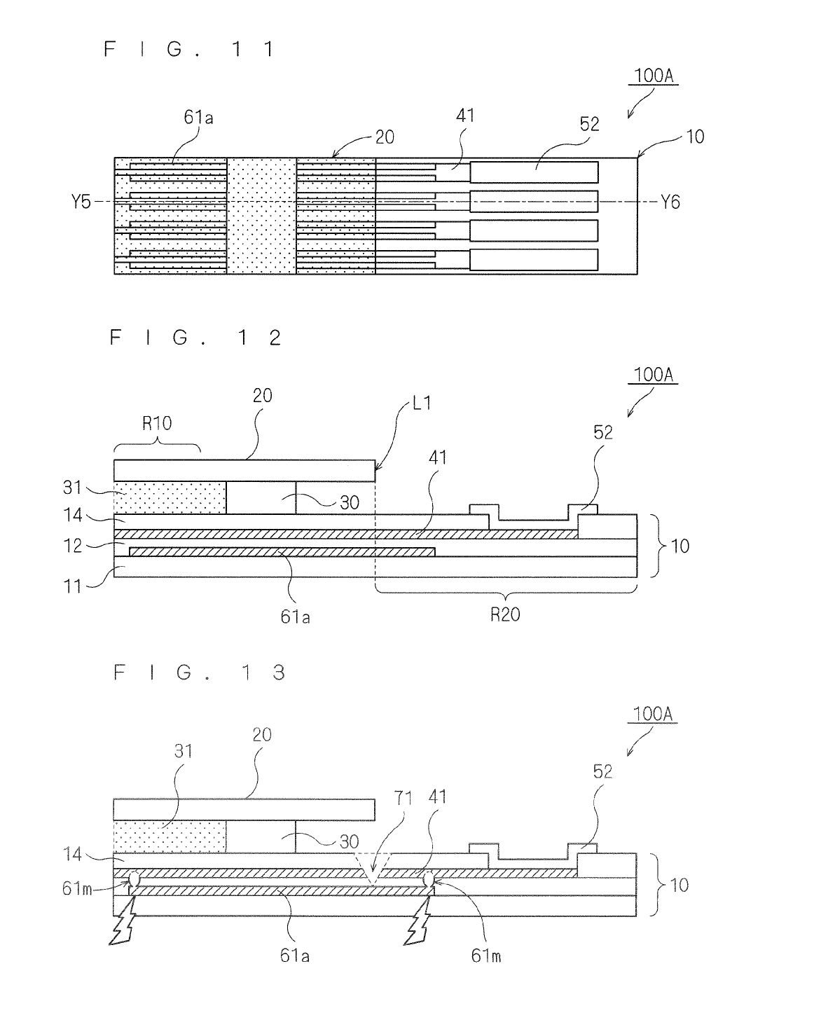

As shown in FIG. 13, it is assumed that a flaw 71 causing the disconnection of the source wiring 41 is made in the cutting step in the middle of the manufacture of the display panel 100A. In this case, a repair process is carried out in the same manner as in the first preferred embodiment. In other words, a laser repairing device or the like irradiates two places of the redundant pattern 61a with a laser beam, the two places of the redundant pattern 61a being close to two places of the source wiring 41 interposing the flaw 71 (a disconnected portion), respectively. Consequently, a part of the redundant pattern 61a is molten so that a molten portion 61m is generated. The two places of the source wiring 41 interposing the flaw 71 therebetween are electrically connected through the redundant pattern 61a by the molten portion 61m. In other words, the redundant pattern 61a electrically connects the two places of the source wiring 41 through irradiation of the laser beam on the two places of the redundant pattern 61a which are respectively close to the two places of the source wiring 41 interposing the disconnected portion (the flaw 71) therebetween.

From the foregoing, the redundant pattern 61a is used for electrically connecting the two places of the source wiring 41 which interpose the disconnected portion (the flaw 71) therebetween when the disconnected portion (the flaw 71) is present in the source wiring 41 in the vicinity of the redundant pattern 61a. In other words, the redundant pattern 61a serves to avoid the influence of the failure such as the disconnection of the source wiring 41. More specifically, the redundant pattern 61a serves to avoid the influence of a failure such as the disconnection of the source wiring 41.

Consequently, a place in which the flaw 71 causing the disconnection of the source wiring 41 is made is avoided so that the disconnection of the source wiring 41 is restored. Therefore, it is possible to suppress deterioration in a manufacturing yield.

In the display panel 100 according to the first preferred embodiment, it is necessary to provide two connected portions through a laser beam in a narrow area. For this reason, it is necessary to dispose an area having a certain size for connection through the laser beam.

On the other hand, in the present preferred embodiment, two places to be irradiated with the laser beam in the redundant pattern 61a are disposed sufficiently apart from each other as shown in FIG. 13. For this reason, it is not necessary to enlarge the area for the connection through the laser beam. Therefore, it is possible to suppress increase in the size of the display panel 100.

Also in the display panel 100A according to the present preferred embodiment, the redundant pattern 61a may be formed corresponding to gate wiring 42 in place of the source wiring 41 in the same manner as in the first preferred embodiment. In other words, the redundant pattern 61a may be provided to be extended in a direction (an X-axis direction) in which the gate wiring 42 is extended in order to avoid the influence of the failure of the gate wiring 42.

### Third Preferred Embodiment

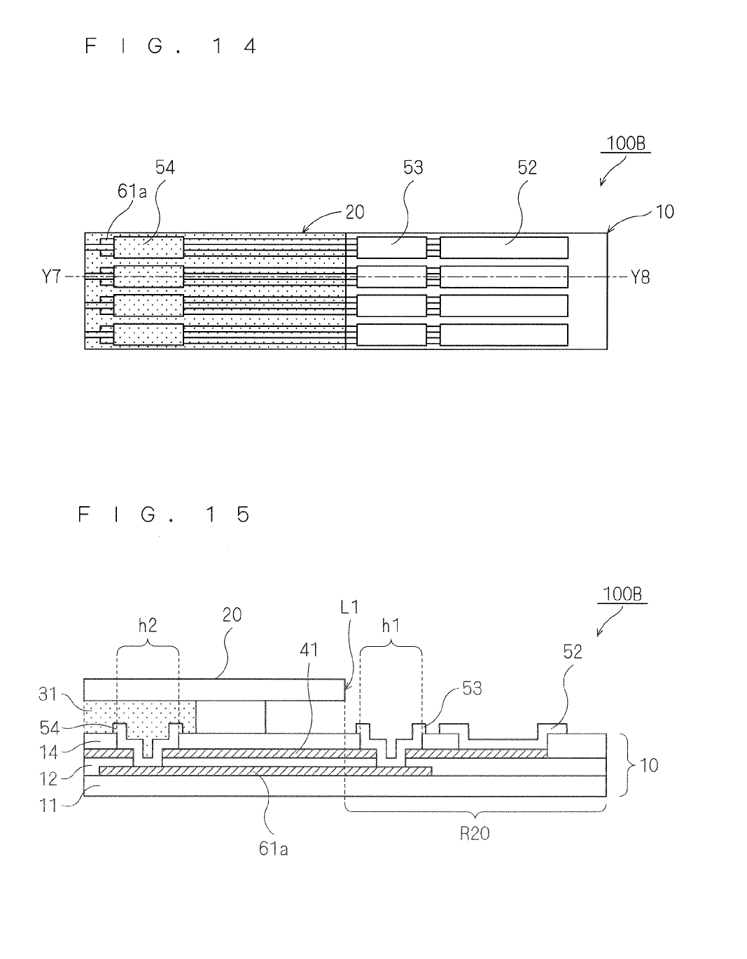

FIG. 14 is a plan view showing a part of a display panel 100B according to a third preferred embodiment of the present invention. FIG. 14 is an enlarged view showing a part of the display panel 100B in the same manner as FIG. 3. FIG. 15 is a sectional view showing the display panel 100B taken along a Y7-Y8 line in FIG. 14. A display device according to the present preferred embodiment includes the display panel 100B.

With reference to FIGS. 14 and 15, the display panel 100B is further different from the display panel 100A shown in FIG. 12 in that the display panel 100B further includes conductive films 53 and 54. Since the other structures of the display panel 100B are the same as those of the display panel 100A, detailed description will not be repeated.

Contact holes h1 and h2 are formed on a substrate 10 of the display panel 100B. The contact holes h1 and h2 are formed on a passivation film 14 and an interlayer insulating film 12 in the substrate 10 in the state of part (f) in FIG. 6. A redundant pattern 61a is electrically connected to source wiring 41 through the contact holes h1 and h2. The conductive films 53 and 54 are provided after the formation of the contact holes h1 and h2.

Specific description will be given below. The conductive film 53 is formed in the contact hole h1. The conductive film 53 electrically connects one of ends of the redundant pattern 61a to the source wiring 41. The conductive film 54 is formed in the contact hole h2. The conductive film 54 electrically connects the other end of the redundant pattern 61a to the source wiring 41. In other words, the redundant pattern 61a and the source wiring 41 are electrically connected in parallel with each other.

By the structure, for example, it is assumed that a flaw is made in an opposed part to a cutting line L1 in the source wiring 41 in the cutting step. Also in this case, there is maintained a state in which two places of the source wiring 41 interposing the flaw therebetween are electrically connected through the conductive films 53 and 54 and the redundant pattern 61a. For this reason, it is possible to prevent the source wiring 41 from being disconnected. In other words, the redundant pattern 61a according to the present preferred embodiment serves to avoid the influence of the failure such as the disconnection of the source wiring 41.

Moreover, by the structure, an inspection in a manufacturing process can be eliminated. Furthermore, even if a product (a display device including the display panel 100B) is used in a market, it is possible to prevent a delay of the disconnection from occurring.

Moreover, according to the structure, it is not necessary to carry out a repair process using a laser beam utilizing the redundant pattern 61 different from the first and second preferred embodiments. For this reason, it is possible to eliminate the influence of a damage of an irradiated portion through laser beam irradiation and a factor of an instability in a contact characteristic of a metal in the two places through the connection with the laser beam. As a result, according to the present preferred embodiment, it is possible to obtain a display panel having higher reliability than that in each of the first and second preferred embodiments and a display device including the display panel.

Also in the display panel 100B according to the present preferred embodiment, the redundant pattern 61a may be formed corresponding to gate wiring 42 in place of the source wiring 41 in the same manner as in the first preferred embodiment. In other words, the redundant pattern 61a may be provided to be extended in a direction (an X-axis direction) in which the gate wiring 42 is extended in order to avoid the influence of a failure of the gate wiring 42. In this case, the conductive films 53 and 54 are provided to electrically connect one of the ends and the other end in the redundant pattern 61a to the gate wiring 42.

### Fourth Preferred Embodiment

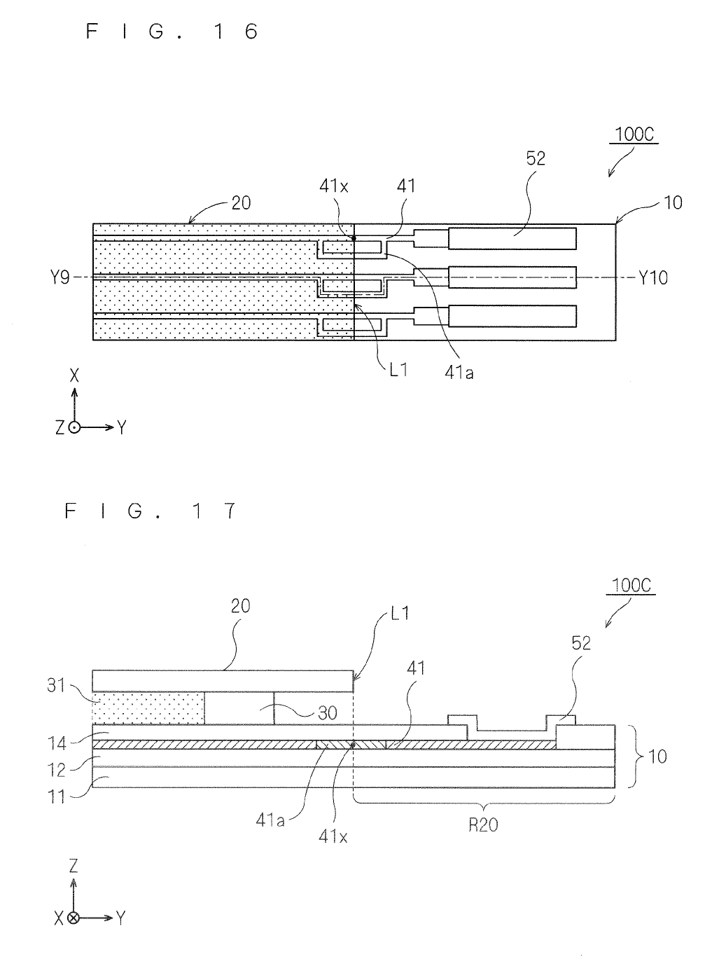

FIG. 16 is a plan view showing a part of a display panel 100C according to a fourth preferred embodiment of the present invention. FIG. 16 is an enlarged view showing a part of the display panel 100C in the same manner as FIG. 3. In FIG. 16, for simplification of the drawing, a part of components (for example, a sealing material 30) is not shown.

FIG. 17 is a sectional view showing the display panel 100C taken along a Y9-Y10 line in FIG. 16. A display device according to the present preferred embodiment includes the display panel 100C.

With reference to FIGS. 16 and 17, the display panel 100C is different from the display panel 100A in FIG. 12 in that the display panel 100C includes a redundant pattern 41a in place of the redundant pattern 61a.

The redundant pattern 41a is connection wiring (second wiring) which is different from the source wiring 41 acting as first wiring. The redundant pattern 41a is formed in a position substantially identical to the source wiring 41 in a vertical direction (a Z-axis direction) of a substrate 10. The redundant pattern 41a is provided in a direction of a main surface of the substrate 10 in the source wiring 41. In other words, in FIG. 16, a plurality of pieces of wiring including the redundant pattern is disposed on a plane basis in the vicinity of places interposing a cutting line L1 in the substrate 10.

Moreover, the redundant pattern 41a is electrically connected to two places of the source wiring 41 provided across a position of the cutting line L1. More specifically, the redundant pattern 41a is electrically connected to two places of the source wiring 41 which interpose a portion (a portion 41x) opposed (corresponding) to the cutting line L1 in the source wiring 41. In other words, the redundant pattern 41a is electrically connected to the source wiring 41 in parallel.

Consequently, the redundant pattern 41a functions as a bypass pattern of the source wiring 41. More specifically, in the present preferred embodiment, the bypass pattern (the redundant pattern 41a) is formed in a part of the source wiring 41. From the foregoing, the display panel 100C has a redundant structure in which a plurality of pieces of wiring is connected in parallel in the same wiring layer.

By the structure described above, in the present preferred embodiment, even if a flaw is made in the vicinity of the portion 41x of the source wiring 41 in the cutting step, for example, it is not necessary to carry out a repair process by a laser beam. Moreover, with the structure according to the present preferred embodiment, it is not necessary to form a contact hole to connect the source wiring 41 to the redundant pattern different from the third preferred embodiment. Therefore, according to the structure in accordance with the present preferred embodiment, it is possible to obtain a display panel having a more stable characteristic and higher reliability than those in the third preferred embodiment and a display device including the display panel.

Although there is employed the structure in which the bypass pattern (the redundant pattern 41a) is formed in a part of the wiring (the source wiring 41) as described above, the present invention is not restricted to the structure. For example, it is also possible to employ a structure in which one of ends of the redundant pattern 41a is not connected to the source wiring 41. With the structure, in the case in which a failure such as disconnection occurs, one of the ends of the redundant pattern 41a is irradiated with a laser beam to connect the end of the redundant pattern 41a to the source wiring 41 in the same manner as in the repair process. Consequently, it is possible to obtain the same effects as those in the first preferred embodiment.

Also in the display panel 100C according to the present preferred embodiment, the redundant pattern 41a may be formed corresponding to gate wiring 42 in place of the source wiring 41 in the same manner as in the first preferred embodiment. In other words, the redundant pattern 41a may be formed corresponding to the gate wiring 42 in order to avoid the influence of a failure of the gate wiring 42. More specifically, it is also possible to employ a structure in which one of the ends and the other end in the redundant pattern 41a are electrically connected to the gate wiring 42.

In the present invention, the respective preferred embodiments can freely be combined within the range of the invention or can properly be changed and omitted.

The present invention can be utilized as a display panel capable of avoiding the influence of a failure occurring in the vicinity of a circuit component mounting area.

While the invention has been shown and described in detail, the foregoing description is in all aspects illustrative and not restrictive. It is therefore understood that numerous modifications and variations can be devised without departing from the scope of the invention.

What is claimed is:

1. A display panel comprising:
a first substrate having a display area for displaying a video and a circuit component mounting area formed around the display area for mounting a circuit component thereon; and
a second substrate disposed opposite to said first substrate,
wherein said second substrate is formed by cutting a part of a substrate disposed opposite to said first substrate along a cutting line for exposing said circuit component mounting area, and
said first substrate includes:
first wiring extended from an inner part of said display area to said circuit component mounting area; and
a redundant pattern formed in a position corresponding to said cutting line and in the vicinity of said first wiring.

2. The display panel according to claim 1, wherein said redundant pattern is formed in a position which overlaps with a part of said first wiring in a direction along a main surface of said first substrate and is different from said first wiring in a vertical direction of said first substrate.

3. The display panel according to claim 1 further comprising a sealing material for connecting said first substrate to said second substrate,
said cutting line being disposed on an outside of a position of said sealing material, and
said redundant pattern being extended across said position of said sealing material.

4. The display panel according to claim 1, wherein said redundant pattern is used for electrically connecting two places of said first wiring which interpose a disconnected portion therebetween when said disconnected portion is present in said first wiring in the vicinity of said redundant pattern.

5. The display panel according to claim 4, wherein said redundant pattern is constituted by a conductor,
each of said redundant pattern and said first wiring is extended in a predetermined direction and is provided close to each other, and
said redundant pattern electrically connects the two places of said first wiring through irradiation of a laser beam on two places of said redundant pattern which are respectively close to the two places of said first wiring interposing said disconnected portion therebetween.

6. The display panel according to claim 1, wherein said redundant pattern is electrically connected to said first wiring through a contact hole.

7. The display panel according to claim 1, wherein said redundant pattern is second wiring which is different from said first wiring.

8. The display panel according to claim 7, wherein said second wiring is formed in a position substantially identical to said first wiring in a vertical direction of said first substrate, and
said second wiring is electrically connected to two places of said first wiring provided across a position of said cutting line.

9. A display device comprising the display panel according to claim 1.
